(19) United States
(12) Patent Application Publication
(10) Pub. No.: US 2009/0201053 A1
(43) Pub. Date: Aug. 13, 2009

(54) LAYOUT STRUCTURE OF SOURCE DRIVER AND METHOD THEREOF

(75) Inventor: Chih-Hsing Chang, Tainan County (TW)

Correspondence Address: J C PATENTS, INC., 4 VENTURE, SUITE 250, IRVINE, CA, 92618, US

(73) Assignee: HIMAX TECHNOLOGIES LIMITED, Tainan County (TW)

(21) Appl. No.: 12/030,507

(22) Filed: Feb. 13, 2008

(51) Int. Cl. H03K 3/00; H01S 4/00

(52) U.S. Cl. 327/108; 29/592.1

(57) ABSTRACT

A layout structure of a source driver having a plurality of driving channels, and a method thereof are provided herein. The layout structure of the source driver includes a plurality of pads and a plurality of routings. The pads are used for making electric contact between the source driver and an external circuit. The routings are respectively coupled between the driving channels and the pads for transmitting the signal. Besides, the routings respectively includes a plurality of resistance units, and each of the resistance units is used for adjusting the resistance of the respective routing so as to minimize a variation of the driving ability between the pads.

### BACKGROUND OF THE INVENTION

1. Field of the Invention

The present invention relates to a layout structure of a source driver and a method thereof, and more particularly, utilizes the layout technique to minimize a variation of driving ability between the pads of the source driver.

2. Description of Related Art

In recent years, the liquid crystal display (LCD) becomes the main stream in the market due to numerous advantages of the LCD, such as low power consumption, free of radiation, and high space utilization. The source driver is an important component of the LCD, which converts a digital data signal used for displaying an image to an analog signal, and outputs the analog signal to each pixel of the display panel.

FIG. 1A is diagram of a conventional layout structure of the source driver. Referring to FIG. 1A, the layout structure of the source driver 100 includes a central circuit 110, a plurality of driving channels C₁˜Cₙ, and a plurality of pads P₁˜Pₙ. With great advance in the technique of electro-optical and semiconductor devices, the display panel is fabricated with great screen for human to have better visual enjoyment. Hence, the driving channels C₁˜Cₙ of the source driver 100 are raised in number, and the pads P₁˜Pₙ needs to be layout around the source driver 100 by following the layout rules, such as the pitch between the neighboring pads, and the size of the pads P₁˜Pₙ. The pads P₁˜Pₙ are respectively coupled to the driving channels C₁˜Cₙ for electrical connection between the source driver 100 and the conductive lines to an external circuit (not shown in the FIG. 1A). The central circuit 110 performs a signal processing on a data driving signal so that the source driver 100 can transmit the data driving signal to external circuit through the driving channels C₁˜Cₙ and the pads P₁˜Pₙ.

However, the routing lengths between the driving channels C₁˜Cₙ and the respective pads P₁˜Pₙ are different. For example, the routing length between the driving channel C₁ and the respective pad P₁ is greater than the routing length between the driving channel Cⱼ and the respective pad Pⱼ. The resistance of the routing changes as the routing length, which causes the output driving abilities of the pads P₁˜Pₙ non-uniform. FIG. 1B is curve diagram of the resistance of the routing corresponding to each of the driving channels in FIG. 1A. Referring to FIG. 1A and FIG. 1B, it is assumed that there are 480 driving channels. The resistance of the routing gets higher when the driving channel is distant from the central circuit 110. It is noted that the routing length corresponding to the driving channel C₂₄₀ in this example is not shortest in the source driver 100 so that the resistance of the routing corresponding to the driving channel C₂₄₀ is not the minimum. If the driving abilities of the pads P₁˜Pₙ are non-uniform, the band mura or cross talk may appear on the display panel and affect the visual quality. Hence, how to solve the said problem is an important issue in the field.

### SUMMARY OF THE INVENTION

Accordingly, the present invention provides a layout structure of a source driver and a method thereof. The present invention adjust the resistance of the routing corresponding to the respective driving channel of the source driver by utilizing the layout technique for minimizing a variation of driving ability between the pads. Therefore, the present invention can solve the problem of band mura and cross talk appearing on the display panel for better visual quality.

A layout structure of a source driver having a plurality of driving channels is provided in the present invention. The layout structure of the source driver includes a plurality of pads, and a plurality of routings, wherein the routings respectively include a plurality of resistance units. The pads are used for making electric contact between the source driver and an external circuit. The routings are respectively coupled between the driving channels and the pads for transmitting a signal between each driving channel and each respective pad. The resistance unit included in the routing is used for adjusting the resistance of the routing so as to minimize a variation of the driving ability between the pads.

A layout method of a source driver is provided in the present invention, wherein the source driver has a plurality of driving channels. In the layout method of the source driver, a plurality of pads is formed around and inside the source driver for making electric contact between the source driver and an external circuit. A plurality of routings is formed to be respectively coupled between the driving channels and the pads for transmitting a signal between each driving channel and each driving channel. A conductive layer is formed to be integrated into at least one routing so as to minimize a variation of driving ability between the pads.

The present invention provides a layout structure of a source driver and a method thereof that utilize the layout technique to adjust the resistance of the routing. The process variation of the routing and the length of the routing have influence on the resistance of the routing so that there is a variation of driving ability between the pads. Because the size of the display panel grows large, the driving abilities of the pads of the source driver should be maintain similar to avoid the band mura and cross talk appearing on the display panel. In the layout structure and method, the resistance unit, i.e. conductive layer, is fabricated (or called integrated) into the routing to adjust the resistance of the routing so that a variation of the driving ability between the pads can be minimized.

In order to make the features and advantages of the present invention comprehensible, preferred embodiments accompanied with figures are described in detail below.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A is diagram of a conventional layout structure of the source driver.

FIG. 1B is curve diagram of the resistance of the routing corresponding to the driving channels in FIG. 1A.

FIG. 2 is a diagram of a layout structure of a source driver according to an embodiment of the present invention.

FIG. 3A is a diagram of at least one resistance unit according to an embodiment of the present invention.

FIG. 3B and FIG. 3C are the layout diagrams of the resistance unit according to the embodiment of the present invention in FIG. 3A.

FIG. 4A is a diagram of at least one resistance unit according to an embodiment of the present invention.

FIG. 4B is a layout diagram of the resistance unit according to the embodiment of the present invention in FIG. 4A.

FIG. 5A is a diagram of at least one resistance unit according to an embodiment of the present invention.

FIG. 5B is a layout diagram of the resistance unit according to the embodiment of the present invention in FIG. 5A.

FIG. 6 is a curve diagram of the resistance of routing corresponding to the driving channels in FIG. 2 according to an embodiment of the present invention.

FIG. 7 is a curve diagram of the resistance of routing corresponding to the driving channels in FIG. 2 according to an embodiment of the present invention.

FIG. 8 is a flow chart of the layout method of the source driver according to an embodiment of the present invention.

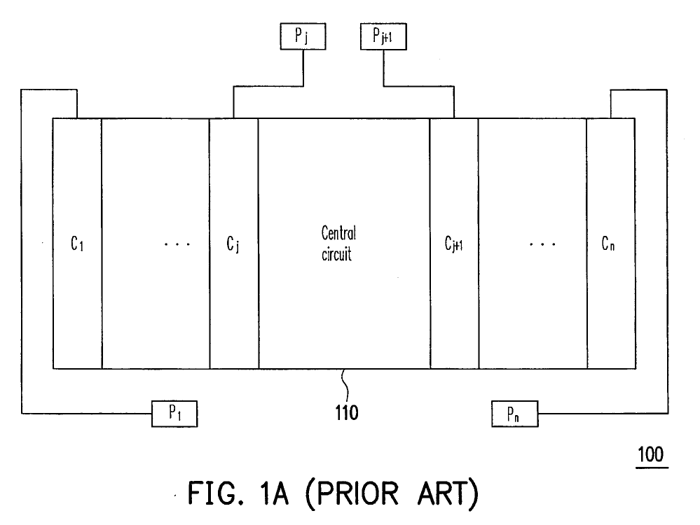

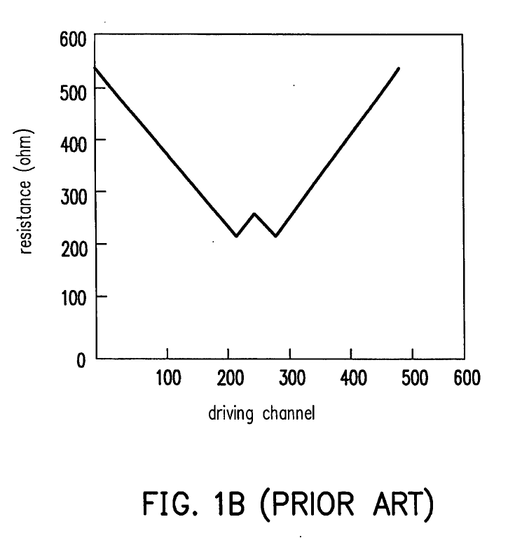

### DESCRIPTION OF EMBODIMENTS

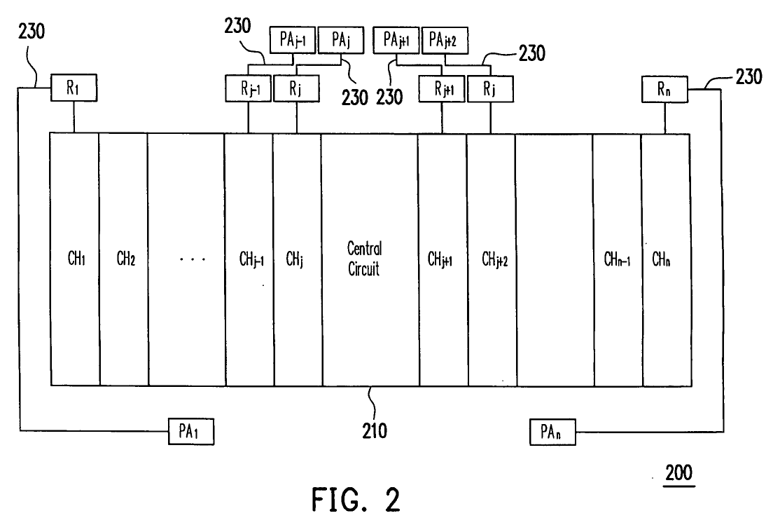

FIG. 2 is a diagram of a layout structure of a source driver according to an embodiment of the present invention. Referring to FIG. 2, the source driver 200 has a plurality of driving channels CH₁˜CHₙ, wherein n is the number of the driving channels. A data driving signal is transmitted to the pixel cells on the data lines through the driving channels CH₁˜CHₙ of the source driver 200. The layout structure of the source driver 200 includes a central circuit 210, a plurality of pads PA₁˜PAₙ, and a plurality of routings 230, wherein the routings 230 respectively include a plurality of resistance unit R₁˜Rₙ. The central circuit 210 performs a signal processing on the data driving signal, for controlling the data transmission. The pads PA₁˜PAₙ are used for making electric contact between the source driver 200 and an external circuit (not illustrated in FIG. 2), such as the pixel cells. The routings 230 are respectively coupled between the driving channels CH₁˜CHₙ and the pads PA₁˜PAₙ. The resistance units R₁˜Rₙ included in the routings 230 are used for adjusting the resistances of the routings 230 so as to minimize a variation of the driving ability between the pads PA₁˜PAₙ. The following describes the resistance units R₁˜Rₙ in detail.

As known, the resistances of the routings 230 changes as the routing length, that is, the longer the routing length is, the higher the resistance of the routing 230 is. Hence, the output driving abilities of the pads PA₁˜PAₙ are non-uniform. Referring to FIG. 2, the routing 230 corresponding to the driving channel CHⱼ is shorter than the routing 230 corresponding to the driving channel CH₁. In the embodiment of the present invention, the resistance unit Rⱼ included in the routing 230 corresponding to the driving channel CHⱼ is applied to increase the routing resistance, and/or the resistance unit R₁ included in the routing 230 corresponding to the driving channel CH₁ is applied to decrease the routing resistance.

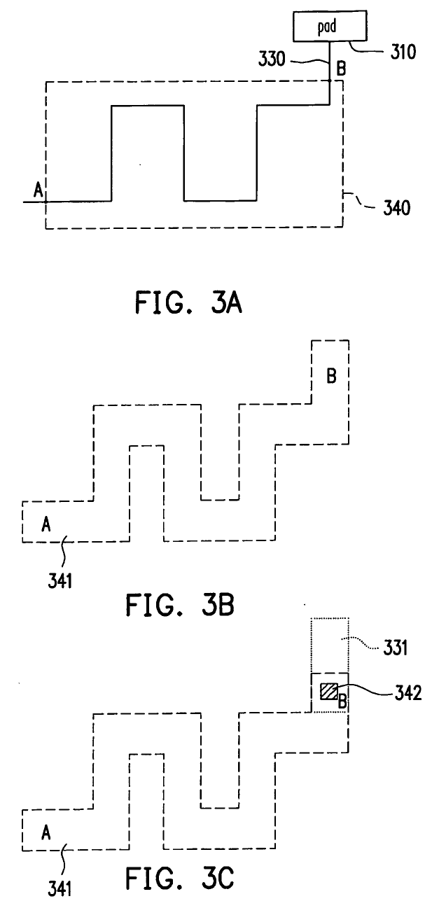

FIG. 3A is a diagram of at least one resistance unit according to an embodiment of the present invention. Referring to FIG. 3A, the resistance unit 340, such as the resistance unit Rⱼ shown in FIG. 2, includes a dummy line being electrical serial connected with the routing 330 for increasing the routing length, which the routing 330 is coupled between the pad 310 and the driving channel CHⱼ. In the embodiment, the dummy line is a conductive line with several turning points. For convenience of description, the sign A and B are marked to show two terminals of the resistance unit 340 respectively coupled to the driving channel CHⱼ and the pad 310 through the routing 330. FIG. 3B is a layout diagram of the resistance unit according to the embodiment of the present invention in FIG. 3A. Referring to FIG. 3A and FIG. 3B, the dummy line included in the resistance unit 340 is composed of a first metal layer 341. The dummy line is electrical serial connected with the routing 330 which is also composed of the first metal layer 341. FIG. 3C is another layout diagram of the resistance unit according to the embodiment of the present invention in FIG. 3A. Referring to FIG. 3A and FIG. 3C, the dummy line included in the resistance unit 340 is composed of a first metal layer 341, and the dummy line is electrical serial connected with the routing 330 composed of a second metal layer 331 by vias 342, wherein the first metal layer 341 is different to the second metal layer 331. In the embodiments of the present invention, the resistance of the routing 330 can be increased by increasing the length of the dummy line.

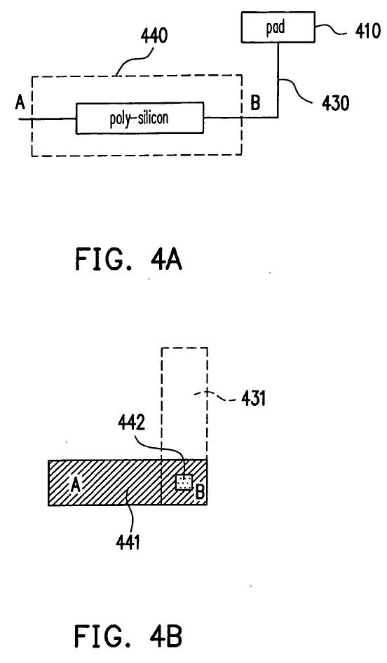

FIG. 4A is a diagram of at least one resistance unit according to an embodiment of the present invention. Referring to FIG. 4A, the resistance unit 440, such as the resistance unit Rⱼ shown in FIG. 2, includes a poly-silicon being electrical serial connected with the routing 430, which the corresponding routing 430 is coupled between the driving channel CHⱼ and the pad 410. For convenience of description, the sign A and B are also marked to show two terminals of the resistance unit 440 respectively coupled to the driving channel CHⱼ and the pad 410 through the routing 430. FIG. 4B is a layout diagram of the resistance unit according to the embodiment of the present invention in FIG. 4A. Referring to FIG. 4A and FIG. 4B, the poly-silicon 441 included in the resistance unit 440 is a material having electric conductivity, and the poly-silicon 441 is electrical serial connected with the routing 430 which is composed of a first metal layer 431 by contacts 442. In the embodiment, the resistance of the routing 430 can be adjusted according to the length of the poly-silicon. The electric conductivity of the poly-silicon is less than the metal layer, that is, utilizing the poly-silicon can increase the resistance of the routing 430. In another embodiment of the present invention, the poly-silicon 441 can be substituted by forming an active region (or referred as a diffusion region) and the active region (not illustrated in FIG. 4B) is also electrical serial connected with the routing 430 which is composed of the first metal layer 431 by contacts 442.

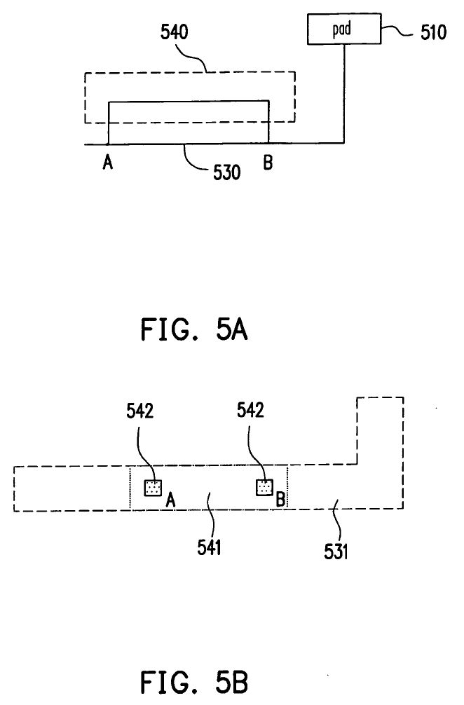

The above-mentioned embodiments of the present invention describe the layout structure and method of increasing the resistance of the routing. FIG. 5A is a diagram of at least one resistance unit according to an embodiment of the present invention. Referring to FIG. 5A, the resistance unit 540, such as the resistance unit R₁ or Rₙ shown in FIG. 2, includes a conducting wire being electrical parallel connected with the routing 530, which the corresponding routing 530 is coupled between the driving channel and the pad 510. For convenience of description, the sign A and B are also marked to show two terminals of the resistance unit 540 respectively coupled to the driving channel and the pad 510 through the parallel-connected routing 530. FIG. 5B is a layout diagram of the resistance unit according to the embodiment of the present invention in FIG. 5A. Referring to FIG. 5A and FIG. 5B, the conducting wire composed of a first metal layer 541 is electrical parallel connection with the routing 530 composed of a second metal layer 531 by vias 542, wherein the first metal layer 541 is different to the second metal layer 531. In the embodiment of the present invention, two different metal layers in parallel connection can decrease the resistance of the routing 530.

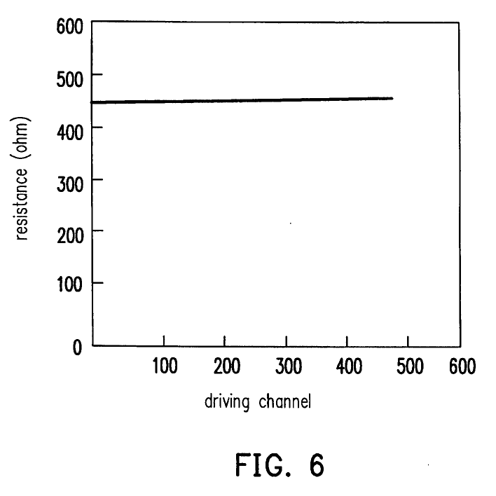

By putting the said embodiments of the present invention into practice, the resistances of routings corresponding to the driving channels CH₁˜CHₙ of the source driver 200 in FIG. 2 can be properly adjusted. For example, by utilizing the said embodiments of the present invention, the resistance of at least one routing can be maintained an average resistance of the routings. FIG. 6 is a curve diagram of the resistance of routing corresponding to the driving channels in FIG. 2 according to an embodiment of the present invention. Referring to FIG. 2 and FIG. 6, it is assumed that there are 480 driving channels in the source driver 200 and the resistances of the routings corresponding to the driving channels CH₁˜CH₄₈₀ tend to be consistent. Hence, the variation of the driving ability between the pads PA₁˜PAₙ is minimized, and the occurrence probability of band mura and cross talk caused by non-uniform driving abilities of the pads PA₁˜PAₙ can be reduced.

The following is another embodiment provided for those skilled in the art to easily implement the present invention. Referring to FIG. 2, if the resistances of the routings 230 are adjusted individually by well designing the resistance unit R₁˜Rₙ, the time schedule for a product, i.e. source driver 200, to be fabricated is too long and the circuit design (or the layout design) is too complicate. In the embodiment of the present invention, the diving channels CH₁˜CHₙ of the source driver 200 are divided into a plurality of groups, and the resistance units coupled to the driving channels in one of the groups are the same. For example, it is assumed that there are 480 driving channels CH₁˜CH₄₈₀ in the source driver 200 and the driving channels CH₁˜CH₄₈₀ are divided into 32 groups in number, that is, the resistance units R₁˜R₃₂ are designed to have the same layout structure, the R₃₃˜R₆₄ are designed to have the same layout structure and so on.

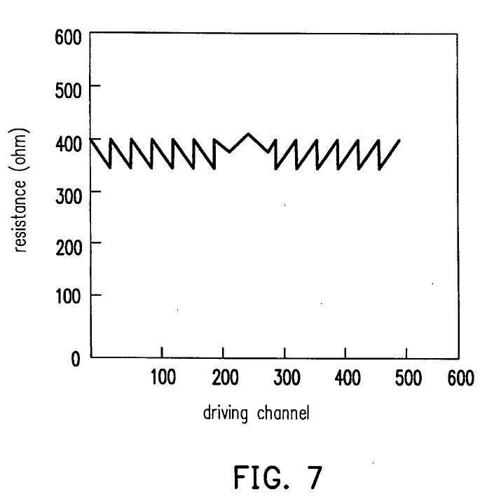

FIG. 7 is a curve diagram of the resistance of routing corresponding to the driving channels in FIG. 2 according to an embodiment of the present invention. Referring to FIG. 2 and FIG. 7, in the premise of dividing the driving channels of the source driver 200 into a plurality of groups and designing the resistance units coupled to the driving channels in one of the groups to have the same layout structure, the resistances of the routings 230 are not consistent, but they only have small difference mutually. Therefore, the variation of the driving ability between the pads PA₁˜PAₙ also can be minimized.

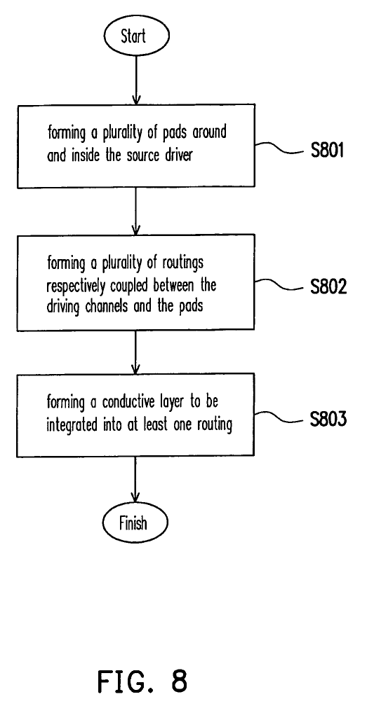

According to the embodiment described above, the steps of the following method could be generalized. FIG. 8 is a flow chart of the layout method of the source driver according to an embodiment of the present invention. Referring to FIG. 2 and FIG. 8, in step S801, a plurality of pads PA₁˜PAₙ are formed around and inside the source driver 200 and used for making electric contact between the source driver 200 and the external circuit. Next, a plurality of routings 230 are formed to be coupled between the driving channels CH₁˜CH₄₈₀ and the pads PA₁˜PAₙ for transmitting the signal in the step S802, and a conductive layer, such as any one or combination of the metal layer, poly-silicon and active region, is formed to be integrated into the said routings in the step S803 so as to minimize a variation of driving ability between the pads PA₁˜PAₙ.

In summary, the embodiments of the present invention utilize the conductive layer, such as the metal layer or poly-silicon, to be electrical serial connected with the routings for increasing the resistances of the routings and utilize the conductive layer, such as the metal layer, to be electrical parallel connection with routings for decreasing the resistance of the routings. Therefore, by adjusting the resistances of the routings to be consistent or to have small difference mutually, the variation of the driving ability between the pads can be minimized for solving the problem of band mura and cross talk.

Though the present invention has been disclosed above by the preferred embodiments, they are not intended to limit the present invention. Anybody skilled in the art can make some modifications and variations without departing from the spirit and scope of the present invention. Therefore, the protecting range of the present invention falls in the appended claims.

What is claimed is:

1. A layout structure of a source driver, wherein the source driver has a plurality of driving channels, comprising:
a plurality of pads, for making electric contact between the source driver and an external circuit; and
a plurality of routings, respectively coupled between the driving channels and the pads for transmitting a signal between each driving channel and each pad, and the routings respectively comprise:
a plurality of resistance units, for adjusting the resistances of the routings so as to minimize a variation of the driving ability between the pads.

2. The layout structure of the source driver as claimed in claim 1, wherein at least one resistance unit is a dummy line being electrical serial connected with the corresponding routing for increasing the corresponding routing length.

3. The layout structure of the source driver as claimed in claim 1, wherein at least one resistance unit is a conducting wire being electrical parallel connection with the corresponding routing.

4. The layout structure of the source driver as claimed in claim 1, wherein at least one resistance unit is a poly-silicon being electrical serial connected with the corresponding routing.

5. The layout structure of the source driver as claimed in claim 1, wherein at least one resistance unit comprises an active region being electrical serial connected with the corresponding routing.

6. The layout structure of the source driver as claimed in claim 1, wherein the resistances of the routings are close to an average resistance of the routings.

7. The layout structure of the source driver as claimed in claim 1, wherein the driving channels are divided into a plurality of groups and the resistance units coupled to the driving channels in one of the groups are the same.

8. A layout method of a source driver, wherein the source driver has a plurality of driving channels, comprising:
forming a plurality of pads around and inside the source driver for making electric contact between the source driver and an external circuit;
forming a plurality of routings respectively coupled between the driving channels and the pads; and
forming a conductive layer to be integrated into at least one routing so as to minimize a variation of driving ability between the pads.

9. The layout method of the source driver as claimed in claim 8, wherein the step of forming the conductive layer to be integrated into the at least one routing comprises:
forming a dummy line composed of a first metal layer being electrical connection with the at least one routing composed of a second metal layer by utilizing a plurality of vias, wherein the first metal layer is different to the second metal layer and the dummy line increases the at least one routing length.

10. The layout method of the source driver as claimed in claim 8, wherein the step of forming the conductive layer to be integrated into the at least one routing comprises:
forming a dummy line composed of the first metal layer being electrical serial connected with the at least one routing composed of the first metal layer for increasing the at least one routing length.

11. The layout method of the source driver as claimed in claim 8, wherein the step of forming the conductive layer to be integrated into the at least one routing comprises:
forming a first metal layer being electrical parallel connection with the at least one routing composed of a second metal layer by utilizing a plurality of vias, wherein the first metal layer is different to the second metal layer.

12. The layout method of the source driver as claimed in claim 8, wherein the step of forming the conductive layer to be integrated into the at least one routing comprises:
forming a poly-silicon being electrical serial connected with the at least one routing composed of a first metal layer by utilizing a plurality of contacts.

13. The layout method of the source driver as claimed in claim 8, wherein the step of forming the conductive layer to be integrated into the at least one routing comprises:
forming an active region being electrical serial connected with the at least one routing composed of a first metal layer by utilizing a plurality of contacts.

14. The layout method of the source driver as claimed in claim 8, wherein the resistances of the at least one routing is an average resistance of the routings.
